(19) United States
(12) Patent Application Publication
(10) Pub. No.: US 2014/0014987 A1
(43) Pub. Date: Jan. 16, 2014

(54) METHODS AND APPARATUSES FOR SHIFTING CHROMATICITY OF LIGHT

(71) Applicants: Paul Panaccione, Newburyport, MA (US); Arvind S. Baliga, Lexington, MA (US)

(72) Inventors: Paul Panaccione, Newburyport, MA (US); Arvind S. Baliga, Lexington, MA (US)

(73) Assignee: Luminus Devices, Inc., Billerica, MA (US)

(21) Appl. No.: 13/545,876

(22) Filed: Jul. 10, 2012

(51) Int. Cl. H01L 33/50

(52) U.S. Cl. 257/98; 257/E33.06

(57) ABSTRACT

The present disclosure relates to shifting a chromaticity of light generated from a light-emitting device. A light-emitting device may incorporate an optical element (e.g., filter) so that light emitted from a light-generating surface having an initial chromaticity may be altered. The optical element may shift the chromaticity of emitted light having the initial chromaticity to a final chromaticity that is different from the initial chromaticity. Thus, the chromaticity of emitted light from the manufactured LEDs that would otherwise be unacceptable for having chromaticity coordinates that fall outside of a desired chromaticity bin is shifted so as to have chromaticity coordinates that fall within suitable parameters. Accordingly, a number of the manufactured LEDs that would normally be discarded may be salvaged.

### BACKGROUND

1. Field

Light-emitting devices, and related components, processes, systems, and methods are generally described. In some embodiments, systems and methods relate to shifting a chromaticity of emitted light.

2. Discussion of Related Art

A light-emitting diode (LED) is a light-emitting device that often can produce light in a more efficient manner than other light-emitting devices, such as incandescent light sources and/or fluorescent light sources. The relatively high power operation and efficiency associated with LEDs has created an interest in using LEDs to displace conventional light sources in a variety of lighting applications. For example, in some instances, LEDs are being used as traffic lights and to illuminate cell phone keypads and displays.

Typically, an LED is formed of multiple layers, with at least some of the layers being formed of different materials. In general, the materials and thicknesses selected for the layers determine the range of wavelength and chromaticity of light emitted by the LED. In addition, the chemical composition of the layers can be selected so as to isolate injected electrical charge carriers into regions (commonly referred to as quantum wells) for relatively efficient conversion to optical power. Generally, the layers on one side of the junction where a quantum well is grown are doped with donor atoms that result in high electron concentration (such layers are commonly referred to as n-type layers), and the layers on the opposite side are doped with acceptor atoms that result in a relatively high hole concentration (such layers are commonly referred to as p-type layers).

During use, electrical energy is usually injected into an LED and then converted into electromagnetic radiation (light), some of which is extracted from the LED, for example, via an emission surface.

LEDs are configured to emit light having a particular color. Colors can be characterized by referencing a standard x, y chromaticity map, depicted in FIGS. 1A and 1B (shown in grayscale), where certain x, y coordinates refer to certain colors. For example, various portions of the x, y chromaticity map correspond to various color regions (FIG. 1A) and color temperatures (FIG. 1B). As shown in FIG. 1B, color temperature may be described in units of absolute temperature (K). During manufacture, depending on the type of light emitted, such as wavelength and chromaticity, LEDs can be categorized according to various chromaticity bin distributions.

### SUMMARY

The inventors have recognized that it may be advantageous to shift a chromaticity of light emitted from a light-emitting device (e.g., LED). The light-emitting device may include a chip having a multi-layer stack with semiconductor materials and including a light-generating region. A package associated with the chip may include an optical element that is configured to shift a chromaticity of light emitted from a surface of the light-generating region. The optical element may bring about a chromaticity shift in any suitable direction and/or magnitude in light emitted from a light-generating region.

The inventors have further appreciated that when LEDs are manufactured to suit certain specifications, absent a suitable optical element used in accordance with aspects of the present disclosure, a number of the manufactured LEDs turn out to emit light having a chromaticity that falls outside of the boundaries defining the preferred chromaticity bin distribution. As a result, a fraction of the manufactured LEDs are often discarded for not meeting suitable chromaticity requirements. However, aspects of the present disclosure provide for the chromaticity of emitted light from the manufactured LEDs that would otherwise not meet the preferred parameters (e.g., is not in accordance with factory specifications for chromaticity) to shift in a manner such that the resulting chromaticity of emitted light from the manufactured LEDs does fall within the preferred parameters. In some embodiments, an optical element may be suitably employed to shift the chromaticity of light emitted from the manufactured LEDs (e.g., those that would normally be wasted) to produce light having a resulting chromaticity that falls within a suitable chromaticity bin distribution. Thus, by appropriately shifting the chromaticity of emitted light, manufactured LEDs that would otherwise be unacceptable for use within preferred parameters would subsequently meet desired chromaticity specifications and be salvaged.

In an illustrative embodiment, a light-emitting device is provided. The light-emitting device includes a chip having a multi-layer stack comprising semiconductor materials and including a light-generating region. The device also includes a package associated with the chip. The package includes an optical element configured to shift a chromaticity of light emitted from a surface of the light-generating region.

In another illustrative embodiment, a method of operating a light-emitting device is provided. The method includes emitting light from a surface of a chip, wherein the chip comprises a multi-layer stack of semiconductor materials and including a light-generating region; and shifting a chromaticity of the emitted light with an optical element, wherein the optical element is part of a package associated with the chip.

Advantages, novel features, and objects of the invention will become apparent from the following detailed description of the invention when considered in conjunction with the accompanying drawings, which are schematic and which are not intended to be drawn to scale. For purposes of clarity, not every component is labeled in every figure, nor is every component of each embodiment of the invention shown where illustration is not necessary to allow those of ordinary skill in the art to understand the invention.

### BRIEF DESCRIPTION OF THE DRAWINGS

The accompanying drawings are not intended to be drawn to scale. In the drawings, each identical or nearly identical component that is illustrated in various figures is represented by a like numeral. Various embodiments of the invention will now be described, by way of example, with reference to the accompanying drawings, in which:

FIGS. 1A and 1B are depictions of a standard x, y chromaticity map;

FIG. 2A is an illustrative cross-sectional schematic of a light-emitting device;

FIG. 2B is a depiction of the shift in chromaticity of light generated from light-emitting devices, as illustrated on a x, y chromaticity map;

FIG. 3 is an exemplary cross-sectional schematic illustration of a light-emitting diode;

FIG. 4 is a diagram illustrating various positions on the x, y chromaticity map of light produced from several examples of light-emitting devices;

FIG. 5A illustrates a shift in chromaticity of light produced from an example light-emitting device;

FIG. 5B is a graph of transmittance as a function of wavelength for the example of FIG. 5A;

FIG. 6A depicts a shift in chromaticity of light produced from another example light-emitting device;

FIG. 6B is a graph of transmittance as a function of wavelength for the example of FIG. 6A;

FIG. 7A illustrates a shift in chromaticity of light produced from yet another example light-emitting device;

FIG. 7B is a graph of transmittance as a function of wavelength for the example of FIG. 7A;

FIG. 8 is a graph of reflectance as a function of wavelength when using an anti-reflection coating in accordance with some embodiments; and

FIG. 9 shows a graph of transmittance as a function of wavelength for a number of examples of light-emitting devices.

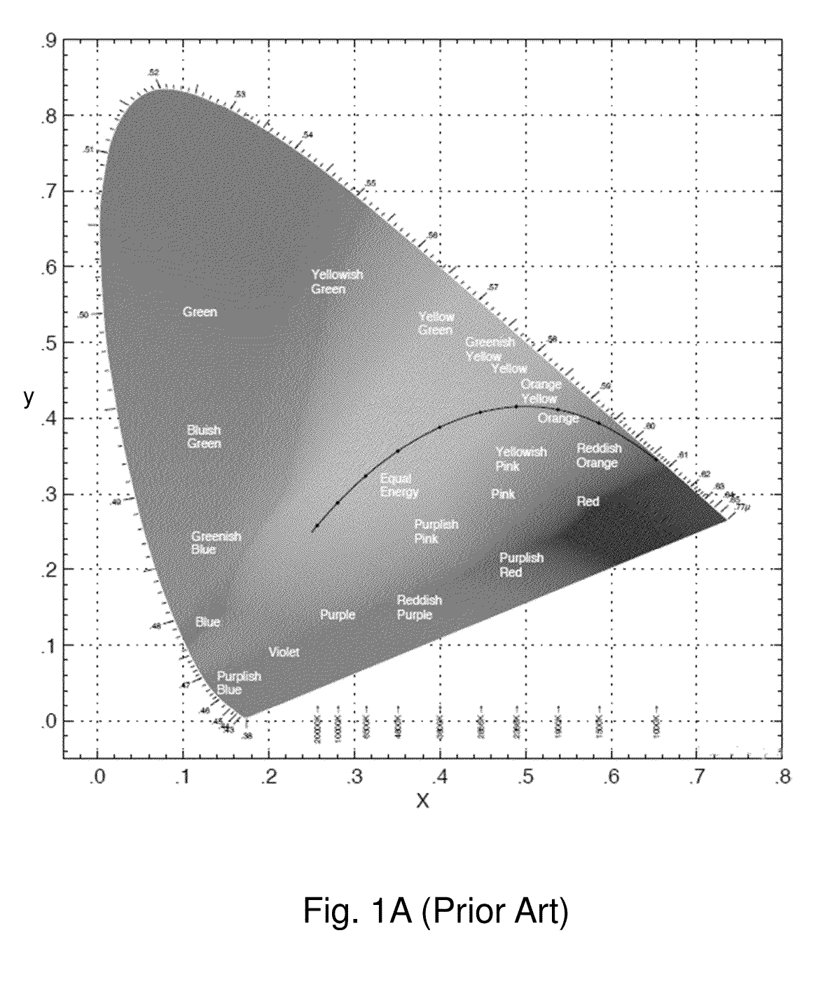

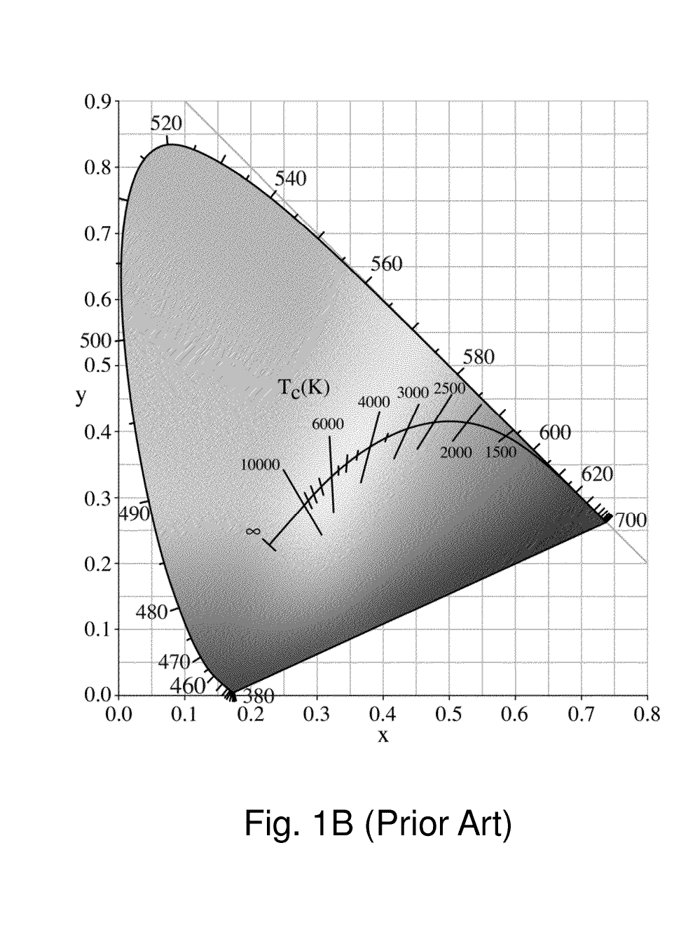

### DETAILED DESCRIPTION

The present disclosure relates to light-emitting devices including light-emitting diodes (LEDs) and related components, processes, systems and methods. As part of a light-emitting device, an optical element may be employed to appropriately shift a chromaticity of light emitted from a surface of a light-generating region of the light-emitting device. In some embodiments, a light-emitting device may include an optical element provided with a package that is associated with a chip (e.g., LED) having a multi-layer stack including semiconductor materials and a light-generating region. For example, the optical element may be positioned adjacent to the light-generating region of the chip, so as to receive and transmit light emitted from the light-generating region.

In some embodiments, the optical element of a light-emitting device may be a component that itself does not actively generate light. For example, the optical element may comprise a filter having a window through which light may be received and transmitted. Accordingly, light emitted from a surface of a light-generating region of a chip may reach and travel through the optical element in a manner that causes the chromaticity of the light to shift. That is, prior to traveling through the optical element, light emitted from the surface of the light-generating region may have an initial chromaticity; though, the resulting chromaticity of the light after having passed through the optical element may be different (e.g., may have different respective x, y coordinates on a chromaticity map) than the initial chromaticity. The optical element may cause the chromaticity of light traveling from the surface of the light-generating region of a chip to shift in other ways. For example, the optical element may, itself, actively generate light in a manner that interacts with light arising from the surface of the light-generating region of the chip so as to result in light having a shifted chromaticity; such an optical element may include an LED and/or other suitable light source. Regardless of the manner in which the chromaticity of light produced from a light-emitting device is shifted, such an adjustment of the emitted light may be appropriate for the light-emitting device to be suitably categorized according to a preferred chromaticity bin.

Systems and methods in accordance with the present disclosure provide advantages in LED production. During manufacture, a number of LEDs will emit light having a chromaticity that falls within the preferred chromaticity bin distribution (e.g., meets ANSI standards). However, as discussed previously, a number of LEDs arising from the manufacture process will almost invariably emit light having a chromaticity that does not fall within the preferred chromaticity bin distribution. Such LEDs which produce light that does not meet preferred chromaticity specifications are often discarded.

Though, aspects of the present disclosure provide for a manner in which manufactured LEDs that emit light having a chromaticity that does not initially meet the preferred chromaticity bin specifications to be salvaged, or made usable according to desired parameters. That is, LEDs that would otherwise be wasted because the chromaticity of emitted light from those LEDs does not meet the chromaticity bin requirements may, instead, be subject to a chromaticity shift so as to bring the emitted light from the LED to within acceptable parameters. For example, when manufacturing white light LED chips, a number of the LEDs may produce light having a chromaticity that does not comply with acceptable parameters. Such chips, or others, can be corrected for by suitably implementing an appropriate optical element in association with the chip so as to shift the chromaticity into a desired bin categorization. Thus, the present disclosure provides for systems and methods of correcting the chromaticity of light emitted from light-emitting devices (e.g., LEDs) such that more manufactured devices will pass the selection test and be permitted to proceed toward the next phase in manufacturing production.

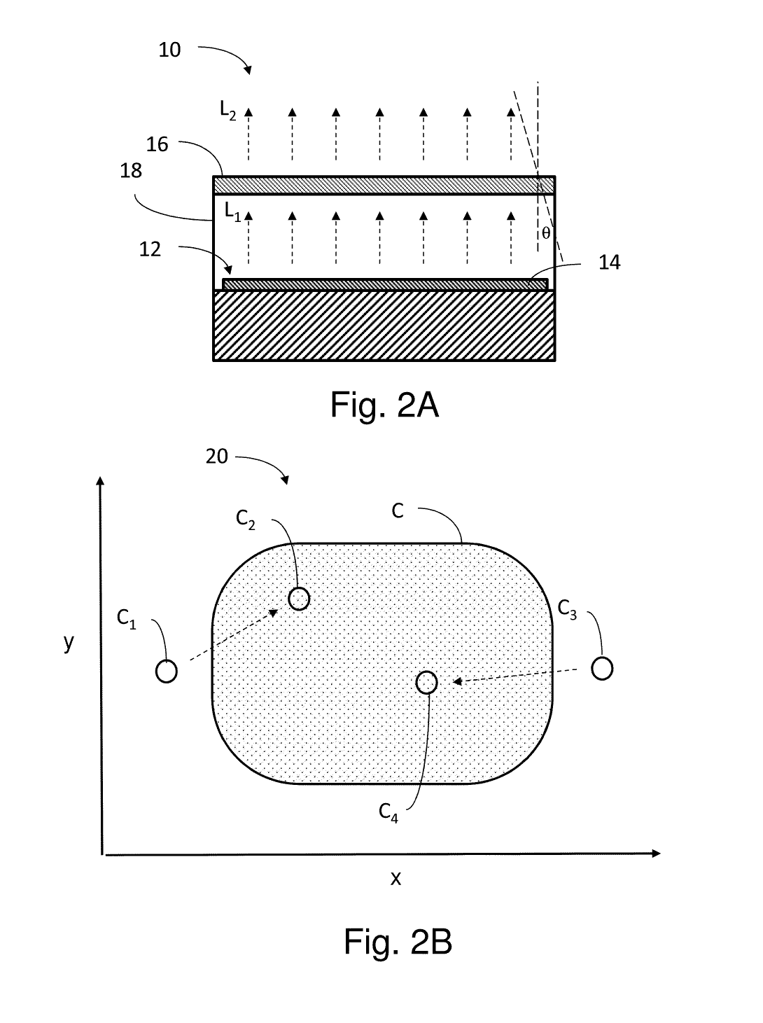

FIG. 2A depicts an illustrative embodiment of a light-emitting device 10 that includes a chip 12 having a light-generating region 14. An optical element 16 is disposed adjacent to the chip 12. The optical element 16 is provided as a filter-type arrangement that receives and transmits light emitted from a surface of the light-generating region 14.

The optical element 16 may include a window having one or more coatings disposed on either side of the window, facing away from the surface of the light-generating region and/or facing toward the surface of the light-generating region. For example, the coatings on the window may enable the optical element to function as a filter that alters certain properties of the light transmitted. In some embodiments, a coating comprising a semiconductor material, such as a metal oxide (e.g., TiO₂, Nb₂O₃, ZnO, ZrO₂, Ta₂O₅, SnO₂, etc.), or any other suitable material, may be disposed on the side of the window facing away from the surface of the light-generating region. Though, it can be appreciated that such a coating may also be disposed on the side of the window facing toward the surface of the light-generating region. Such a coating may cover an entire side or a portion of the window.

In some embodiments, the optical element may include a window having an appropriate anti-reflective coating facing toward the surface of the light-generating region. Though, in some embodiments, the anti-reflective coating may also face away from the surface of the light-generating region. It can be appreciated that other types of materials may be coated on to the window of an appropriate optical element on any suitable side, facing toward and/or away from the surface of the light-generating region. As discussed, an optical element may include a suitable filter. For example, the optical element may be a high-pass filter, a low-pass filter, band-stop filter, a notch filter or any other appropriate filter. In various embodiments, the optical element may be tailored to shift the chromaticity of emitted light in a preferred direction and magnitude to have coordinates on the x, y chromaticity map so as to meet appropriate chromaticity specifications.

FIG. 2A depicts the optical element as a filter having a substantially flat surface that runs perpendicular to the direction which emitted light L₁ generally travels from the surface of the light-generating region; however, any portion of the optical element may have any suitable structure or shape. In some embodiments, the optical element may comprise a single layer or a multiple layered arrangement. The optical element may exhibit a linear slope (e.g., running perpendicular or at angle with respect to the incident light), a patterned structure (e.g., sinusoidal, periodic, etc.), or a structure having irregular shapes or patterns. In some embodiments, various regions of the optical element may have jagged and/or curved edges.

A housing 18 is provided to suitably position (e.g., hold in place) the chip 12 and the optical element 16 with respect to one another. The light-generating region 14 is configured to emit light L₁ from the chip having an initial chromaticity, toward the optical element. The emitted light L₁ travels in a direction indicated by the dashed arrows and passes through the optical element 16. As shown in FIG. 2A, the emitted light L₁ generated from the chip reaches the optical element at an angle of incidence θ of approximately 0 degrees (i.e., the direction in which the light L₁ travels is generally perpendicular to the incident surface of the optical element 16). The optical element is configured to shift the chromaticity of the emitted light L₁ so that shifted light L₂ traveling from the optical element has a resulting chromaticity that is different from the initial chromaticity.

FIG. 2B shows a chromaticity map 20, having x, y coordinates, which illustrates a depiction of a preferred chromaticity bin distribution (shaded) (e.g., within ANSI specifications). It can be appreciated that the preferred chromaticity bin distribution may be defined by any suitable boundaries. Referring to the schematic of FIG. 2A, for an embodiment, the emitted light L₁ from a surface of a light-generating region 14 of the chip 12 has an initial chromaticity C₁ that falls outside of the boundary C of the preferred chromaticity bin distribution. Though, a suitable arrangement of an appropriate optical element 16 with the chip causes the emitted light L₁ to pass through the optical element so as to result in shifted light L₂ traveling away from the light-emitting device 10. The shifted light L₂ has a resulting chromaticity C₂ that falls within the boundary C of the preferred chromaticity bin distribution. The direction and magnitude in which the chromaticity is shifted along the chromaticity map may vary appropriately. For instance, emitted light having an initial chromaticity C₃ falling outside the boundary C of the preferred chromaticity bin distribution may be subject to a chromaticity shift so as to give rise to a resulting chromaticity C₄ that falls within the boundary C of the preferred chromaticity bin distribution.

As discussed, the optical element may be configured to shift the chromaticity of the emitted light from a surface of a light-generating region by any suitable direction and magnitude of chromaticity along the x, y chromaticity map. As used herein, a chromaticity magnitude is a distance between coordinates on the x, y chromaticity map which may be calculated using the following relationship:

chromaticity magnitude=[(x₂−x₁)²+(y₂−y₁)²]^{1/2}

where the chromaticity coordinates for two different points in which chromaticity magnitude is measured on the x, y chromaticity map are (x₁, y₁) and (x₂, y₂).

In some embodiments, the optical element may be configured to shift the chromaticity of emitted light by a chromaticity magnitude along the x, y chromaticity map of greater than about 0.001, greater than about 0.002, greater than about 0.005, greater than about 0.007, greater than bout 0.01, greater than about 0.02, greater than about 0.03, greater than about 0.05, greater than about 0.07, greater than about 0.1, greater than about 0.12, greater than about 0.13, greater than about 0.14, greater than about 0.15, greater than about 0.17, or greater than about 0.2. In some embodiments, the optical element may be configured to shift the chromaticity of the emitted light by a chromaticity magnitude of between about 0.001 and about 0.2, between about 0.001 and about 0.02, between about 0.001 and about 0.015, between about 0.005 and about 0.01, between about 0.001 and about 0.005, between about 0.001 and about 0.002, between about 0.002 and about 0.008, between about 0.002 and about 0.005, between about 0.005 and about 0.008, between about 0.01 and about 0.015, between about 0.015 and about 0.02, between about 0.02 and about 0.03, between about 0.03 and about 0.04, between about 0.04 and about 0.05, between about 0.05 and about 0.06, between about 0.06 and about 0.07, between about 0.07 and about 0.08, or between about 0.08 and about 0.09. In some embodiments, the optical element may be configured to shift the chromaticity of the emitted light by a chromaticity magnitude of between about 0.10 and about 0.2, between about 0.12 and about 0.2, between about 0.15 and about 0.2, between about 0.11 and about 0.19, between about 0.12 and about 0.18, between about 0.13 and about 0.17, or between about 0.14 and about 0.16.

As previously discussed, the optical element may be configured to shift the chromaticity in any suitable direction along the x, y chromaticity map. Thus, the chromaticity, as represented on the chromaticity map, may be shifted in any direction 360 degrees around a corresponding point having x, y coordinates. For instance, as illustrated in FIG. 2B, light originating from a light-generating region of a chip having initial chromaticities C₁, C₃ is subject to respective chromaticity shifts having a suitable direction and magnitude (indicated by the dashed arrows), giving rise to resulting chromaticities C₂, C₄.

In some embodiments, the optical element may be selected from a variety of optical elements that are each configured to shift the chromaticity of emitted light by a particular direction and magnitude. Accordingly, depending on what the chromaticity of emitted light is from a chip (e.g., LED), an appropriate optical element may be chosen to suitably shift the chromaticity so as to fall within a preferred domain. Thus, in some embodiments, different optical elements may be optionally swappable with one another. Alternatively, in some embodiments, an optical element itself may be adjusted according to the desired direction and magnitude of chromaticity shift in the emitted light. That is, if the shift in chromaticity of emitted light caused by an optical element is not acceptable (e.g., does not meet desired specifications), the optical element may be suitably adjusted so that the chromaticity of emitted light is shifted in a preferred manner. The optical element may be adjusted in any suitable manner. For example, a passive optical element may be further coated, tinted, etc.; and an active optical element may be adjusted to emit radiation having different properties, intensity, flux, wavelength, etc.

In some embodiments, once the optical element is implemented in the light-emitting device such that the chromaticity of the emitted light is appropriately shifted, the resulting chromaticity of light falls within a chromaticity bin distribution that is suitable for manufacturing and production standards. In some embodiments, a preferred chromaticity bin distribution within which light produced from the light-emitting device falls has an x-chromaticity that ranges between 0.30 and 0.35, or between 0.303 and 0.322 and a y-chromaticity that ranges between 0.30 and 0.35, or between 0.311 and 0.348. In an embodiment, the boundary of a chromaticity bin distribution according to suitable specification standards may be defined by the following points on the x, y chromaticity map: (0.303, 0.330), (0.321, 0.348), (0.322, 0.326) and (0.307, 0.311). However, it can be appreciated that the optical element may function to shift the chromaticity of light originating from a surface of a light-generating region of a chip such that the resulting chromaticity falls within any suitable scope of chromaticity bin distribution.

The optical element may be configured to shift the chromaticity of light having a suitable wavelength originating from a surface of a light-generating region of the chip. In some embodiments, the light emitted from the surface of the light-generating region has a wavelength of between about 400 nm and about 700 nm, or between about 435 nm and about 665 nm. The optical element may be configured to shift the chromaticity of light having wavelengths not only in the visible light regime of the electromagnetic spectrum, but also in the infrared and ultraviolet regimes. For example, the light emitted from the surface of the light-generating region may have a wavelength of between about 10 nm and about 10 microns, between about 50 nm and about 400 nm, between about 100 nm and about 300 nm, between about 700 nm and about 5 microns, between about 900 nm and about 2 microns, or between about 1 micron and about 1.2 microns. In some embodiments, the optical element may be specially configured to shift the chromaticity of light having a wavelength in a particular regime of the electromagnetic spectrum. Or, the optical element may be able to shift the chromaticity of light having any appropriate wavelength. While the optical element shifts the chromaticity of the emitted light having any suitable wavelength, upon shifting the chromaticity of the emitted light, the wavelength of the light may or may not be altered. In some embodiments, the optical element is configured to shift the chromaticity of light while not altering the wavelength of the light.

In some cases, light distortions may arise when the angle of incidence of light against a component changes. For example, blue halo or yellow halo effects may appear upon alteration of the angle of incidence. Though, in some embodiments, despite modifications of the angle of incidence of emitted light against an optical element, given a chromaticity shift of the light in a suitable direction and magnitude, the resulting chromaticity may fall within a preferred chromaticity bin distribution without substantial distortion in chromaticity of the shifted light. Accordingly, the optical element may cause a suitable shift in the chromaticity of light emitted from a surface of a light-generating region of a chip despite a wide variance of the angle of incidence of light traveling toward the optical element. In some embodiments, the optical element may cause the chromaticity of light to suitably shift according to an appropriate direction and magnitude along the x, y chromaticity map despite the angle of incidence of light traveling toward the optical element varying between 0 degrees and about 50 degrees, between 0 degrees and about 40 degrees, between 0 degrees and about 30 degrees, between 0 degrees and about 20 degrees, between 0 degrees and about 10 degrees, or between 0 degrees and about 5 degrees. For example, the optical element may cause the initial chromaticity of light emitted from an LED to shift to a resulting chromaticity that falls within preferred parameters when the angle of incidence is 0 degrees. When the angle of incidence of light traveling toward the optical element is modified to 30 degrees, for some embodiments, the optical element may still cause the initial chromaticity of light emitted from the LED to shift to a resulting chromaticity falling within preferred parameters.

While suitable arrangements of a light-emitting device that include an appropriate optical element may cause the chromaticity of emitted light to shift in a desirable manner, the flux of light initially emitted from a surface of the light-generating region of the chip may be reduced. For instance, an optical element that shifts the chromaticity of light when light passes through the optical element (e.g., a filter having a window through which light is transmitted), the flux (and corresponding intensity) of the light having passed through the optical element may be reduced. Referring to FIG. 2A as an example, the emitted light L₁ originating from the light-generating region 14 has an initial flux; however, the light L₂ having passed through the optical element 16 may have a flux that is less than the initial flux of L₁. However, in some embodiments, such a reduction in flux of the light initially emitted from the surface of the light-generating region may be small. The percent reduction of flux of the light may be given by a percentage, calculated by the following relationship:

Percent Reduction in Flux (%)=[(Initial flux of light L₁)−(Final flux of light L₂)/(Initial flux of light L₁)*100

In some embodiments, the optical element may be configured such that the flux of the light produced from the light-emitting device is reduced from the initial flux of light produced from the surface of the light-generating region of the chip by an amount less than about 15%, less than about 10%, less than about 8%, less than about 6% or less than about 4%.

The intensity of light is characterized as the flux divided by the area through which the light passes. Accordingly, in some embodiments, the percent reduction in intensity of the light produced from the light-emitting device that is initially generated from the surface of the light-generating region of the chip is approximately equal to the corresponding percent reduction in flux (when the area through which light passes remains constant). However, for instances where the area through which light passes varies in a light-emitting device, the percent reduction of flux may differ from the percent reduction of intensity.

The change in flux or intensity of light produced from the light-emitting device as compared to the initial flux of light produced from the surface of the light-generating region of the chip may be measured by a percent transmittance. Accordingly, the less the flux or intensity of light is reduced, the greater the transmittance through the optical element. In some embodiments, percent transmittance through an optical element is greater than about 80%, greater than about 85%, greater than about 90%, greater than about 92%, greater than about 94%, greater than about 96%, or greater than about 98%.

While the chromaticity of emitted light may shift in a desirable manner, other characteristics of the emitted light may be maintained. For instance, the flux, intensity, color rendering index, wavelength, and other parameters of the emitted light may remain substantially unchanged as the chromaticity of emitted light is suitably shifted.

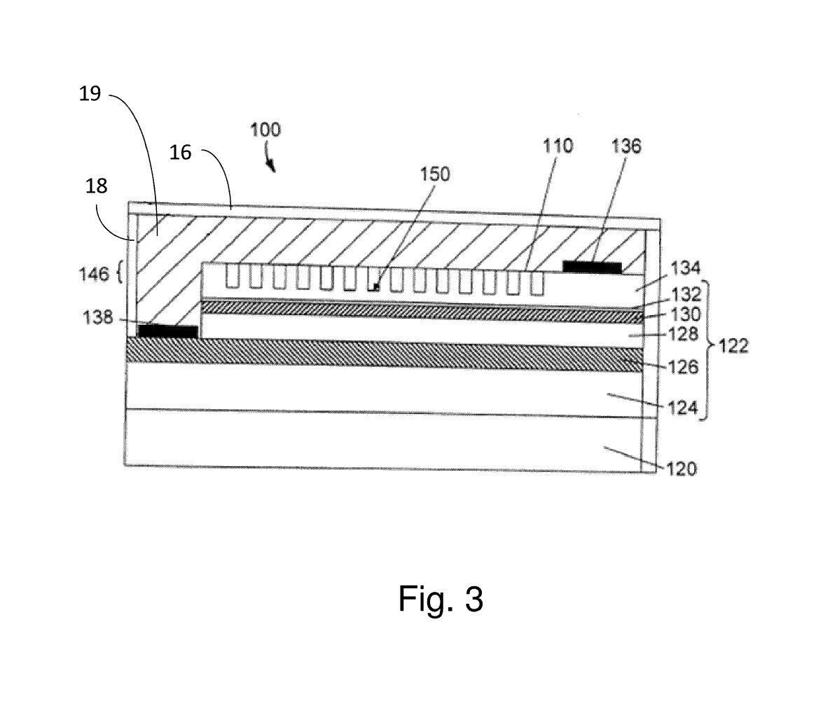

FIG. 3 includes an exemplary cross-sectional schematic illustration of LED 100 in the form of a packaged die, which can be used in accordance with the embodiments described herein. LED 100 includes a multi-layer stack 122 disposed on a submount 120. Multi-layer stack 122 includes a 320 nm thick silicon doped (n-doped) GaN layer 134 having a pattern of openings 150 in its upper surface 110. Multi-layer stack 122 also includes a bonding layer 124, a 100 nm thick silver layer 126, a 40 nm thick magnesium doped (p-doped) GaN layer 128, a 120 nm thick light-generating region 130 formed of multiple InGaN/GaN quantum wells, and a AlGaN layer 132. An n-side contact pad 136 is disposed on layer 134, and a p-side contact pad 138 is disposed on layer 126. An encapsulant material (e.g., epoxy having an index of refraction of 1.5) 19 is optionally present between layer 134 and an optical element 16 and housing 18. Layer 19 generally does not extend into openings 150.

Light is generated by LED 100 as follows. P-side contact pad 138 is held at a positive potential relative to n-side contact pad 136, which causes electrical current to be injected into LED 100. As the electrical current passes through light-generating region 130, electrons from n-doped layer 134 combine in region 130 with holes from p-doped layer 128, which causes region 130 to generate light. Light-generating region 130 contains a multitude of point dipole radiation sources that emit light (e.g., isotropically) within the region 130 with a spectrum of wavelengths characteristic of the material from which light-generating region 130 is formed. For InGaN/GaN quantum wells, the spectrum of wavelengths of light generated by region 130 can have a peak wavelength of about 445 nanometers (nm) and a full width at half maximum (FWHM) of about 30 nm.

It is to be noted that the charge carriers in p-doped layer 126 have relatively low mobility compared to the charge carriers in the n-doped semiconductor layer 134. As a result, placing silver layer 126 (which is conductive) along the surface of p-doped layer 128 can enhance the uniformity of charge injection from contact pad 138 into p-doped layer 128 and light-generating region 130. This can also reduce the electrical resistance of device 100 and/or increase the injection efficiency of device 100. Because of the relatively high charge carrier mobility of the n-doped layer 134, electrons can spread relatively quickly from n-side contact pad 136 throughout layers 132 and 134, so that the current density within the light-generating region 130 is substantially uniform across the region 130. It is also to be noted that silver layer 126 has relatively high thermal conductivity, allowing layer 126 to act as a heat sink for LED 100 (to transfer heat vertically from the multi-layer stack 122 to submount 120).

At least some of the light that is generated by region 130 is directed toward silver layer 126. This light can be reflected by layer 126 and emerge from LED 100 via surface 110, or can be reflected by layer 126 and then absorbed within the semiconductor material in LED 100 to produce an electron-hole pair that can combine in region 130, causing region 130 to generate light. Similarly, at least some of the light that is generated by region 130 is directed toward pad 136. The underside of pad 136 is formed of a material (e.g., a Ti/Al/Ni/Au alloy) that can reflect at least some of the light generated by light-generating region 130. Accordingly, the light that is directed to pad 136 can be reflected by pad 136 and subsequently emerge from LED 100 via surface 110 (e.g., by being reflected from silver layer 126), or the light that is directed to pad 136 can be reflected by pad 136 and then absorbed within the semiconductor material in LED 100 to produce an electron-hole pair that can combine in region 130, causing region 130 to generate light (e.g., with or without being reflected by silver layer 126).

In some embodiments, emitting surface 110 of the LED has a dielectric function that varies spatially which can improve the extraction efficiency of light generated by the LED and may enable the high power levels described further below. For example, the dielectric function can vary spatially according to a pattern. The pattern may be periodic (e.g., having a simple repeat cell, or having a complex repeat super-cell), periodic with de-tuning, or non-periodic. Examples of non-periodic patterns include quasi-crystal patterns, for example, quasi-crystal patterns having 8-fold symmetry. In certain embodiments, the emitting surface is patterned with openings which can form a photonic lattice. Suitable LEDs having a dielectric function that varies spatially (e.g., a photonic lattice) have been described in, for example, U.S. Pat. No. 6,831,302 B2, entitled “Light Emitting Devices with Improved Extraction Efficiency,” filed on Nov. 26, 2003, which is herein incorporated by reference in its entirety.

In some embodiments, performance can be enhanced by placing optical element 16 close to the top surface of the LED. In some embodiments, performance can be enhanced by replacing encapsulant material 19 with air such that the LED emits directly into air.

While the LED shown in FIG. 3 is illustrated as having the n-side contact pad 136 on the top of the LED and the p-side contact pad 138 is on the bottom of the LED, it should be understood that, in other embodiments (e.g., in embodiments in which the LED is fabricated according to a flip-chip process), the p-side contact pad may be on top.

### EXAMPLES

The following examples are intended to illustrate certain embodiments of the present invention, but are not to be construed as limiting and do not exemplify the full scope of the invention.

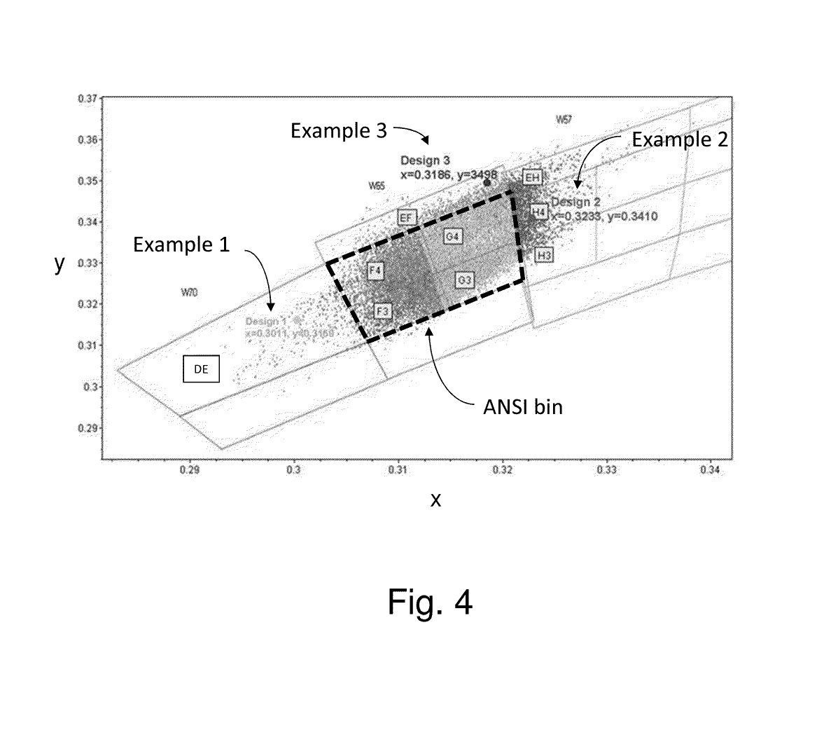

A substantial number of LED chips were manufactured with intention for the LEDs to emit light having a color temperature of 6500 K and having a chromaticity that falls within an ANSI chromaticity bin defined by the following points on the x, y chromaticity map: (0.303, 0.330), (0.321, 0.348), (0.322, 0.326) and (0.307, 0.311). FIG. 4 illustrates where the chromaticity coordinates of light emitted from each LED lie on the x, y chromaticity map. As shown, several of the LEDs naturally emit light falling within suitable zones F3, F4, G3, G4 of the ANSI chromaticity bin. However, a number of LEDs emit light having a chromaticity that lies outside of the ANSI chromaticity bin. Three examples are indicated on the chromaticity map depicted in FIG. 4 as having respective chromaticity coordinates that do not fall within the boundary defining the desired ANSI chromaticity bin. That is, the chromaticity of light emitted from the LED of Example 1 lies within the DE bin; the chromaticity of light emitted from the LED of Example 2 lies within the H4 bin; and the chromaticity of light emitted from the LED of Example 3 lies within the EF bin, as recorded in Table 1.

TABLE 1
Starting x, y chromaticity positions for Examples 1, 2, 3.

| | Starting | Starting | |
|---|---|---|---|
| Example | CIEx | CIEy | Target |
| 1 | 0.3011 | 0.3169 | Move from DE to ANSI bins |
| 2 | 0.3233 | 0.3410 | Move from H4 to ANSI bins |
| 3 | 0.3186 | 0.3498 | Move from EF to ANSI bins |

Though, each of the LEDs of Examples 1, 2, 3 was provided with a corresponding optical filter, similar to that shown in FIG. 2A, where light generated from the surface of each LED having an initial chromaticity was received and transmitted through the respective optical filters. The optical filters were manufactured to include a TiO₂ coating applied on the surface of the window facing away from the light-generating region of the LED chip. An anti-reflection coating was also applied on the surface of each of the windows facing toward the light-generating region of the LED chip. After the light emitted from the respective light-generating regions of each LED passed through respective optical filters, the chromaticity of the light was shifted from an initial chromaticity that had coordinates outside of the preferred ANSI chromaticity bin to a chromaticity that had coordinates within the scope of ANSI standards.

Such a chromaticity shift occurs in a manner such that the amount of flux of the light originated from the surface of the light-generating region of each of the LEDs is substantially maintained after transmission through respective optical filters. For light having wavelengths between 435 nm and 665 nm, the average transmission of light through the optical filter for each of the LEDs of Examples 1, 2, 3 is greater than or equal to 92%.

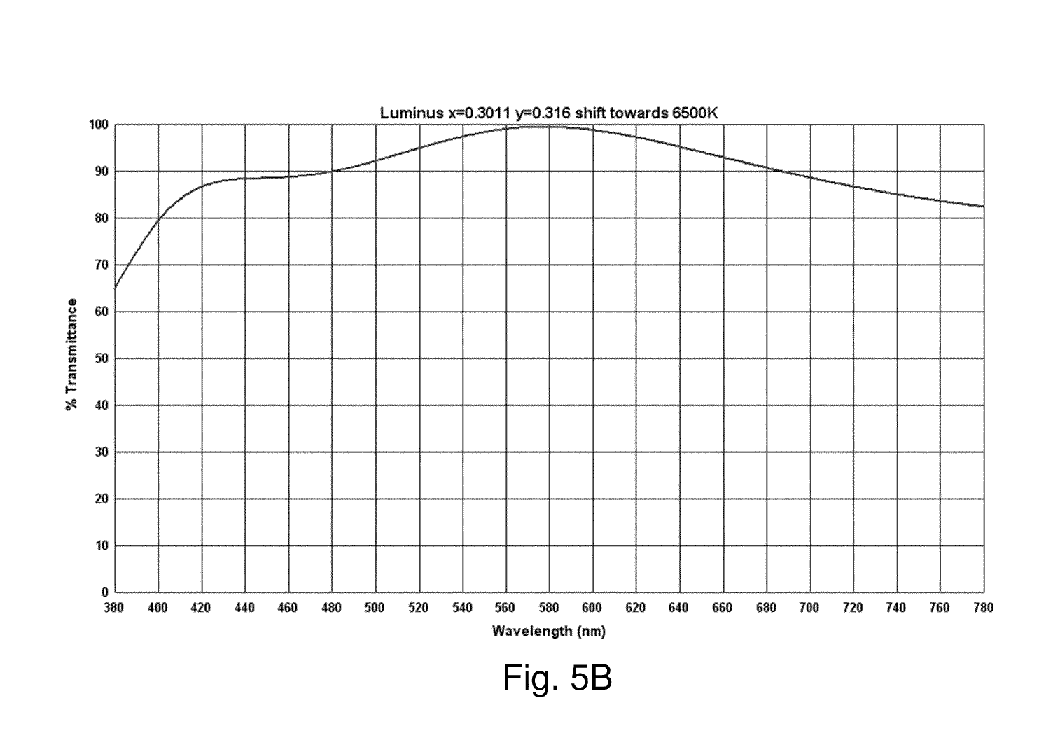

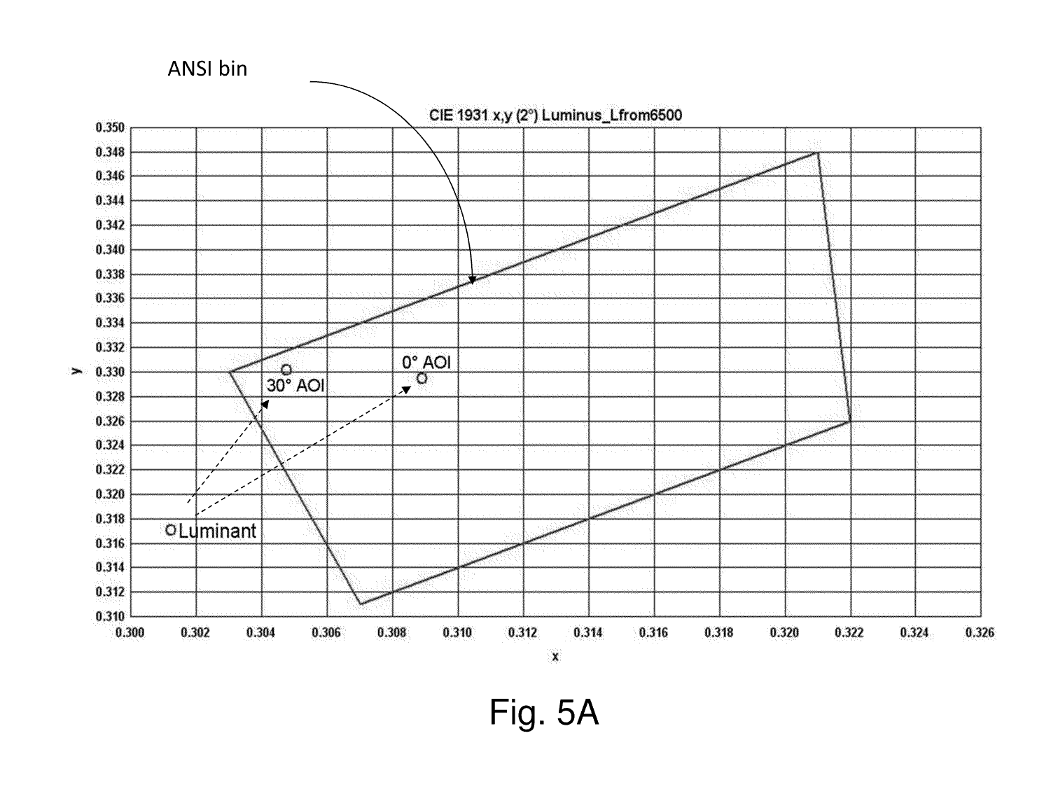

FIG. 5A depicts the shift in chromaticity when light emitted from the LED of Example 1 passes through the optical filter. The emitted light from the LED was directed toward the optical filter at 0 degree and 30 degree angles of incidence. The initial chromaticity for the light emitted from the LED, without the optical filter in place, was (0.3011, 0.3169). On the other hand, the shifted chromaticity for the emitted light having passed through the optical filter at a 0 degree angle of incidence was (0.3089, 0.3295), which is within the preferred ANSI chromaticity bin. Depending on the angle of incidence of light transmitted through the filter, the shift in chromaticity differs. However, the chromaticity of transmitted light through the filter remained within the ANSI bin even if the angle of incidence of light transmitted through the filter was varied between 0 degrees and 30 degrees. FIG. 5B illustrates the transmittance of light through the optical filter as a function of wavelength of the light emitted. For Example 1, the transmittance of light through the filter was observed to be 97.52%.

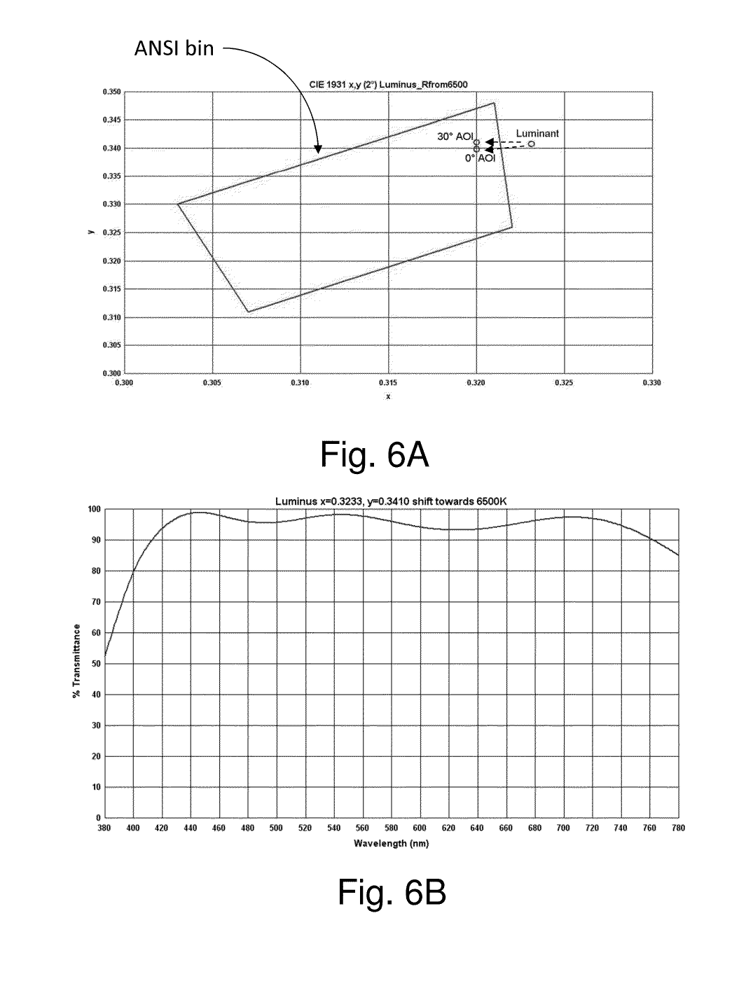

FIG. 6A depicts the shift in chromaticity when light emitted from the LED of Example 2 passes through the optical filter, directed toward the optical filter at 0 degree and 30 degree angles of incidence. The initial chromaticity for the light emitted from the LED, without the optical filter in place, was (0.3233, 0.3410). The shifted chromaticity for the emitted light having passed through the optical filter at a 0 degree angle of incidence was (0.3200, 0.3398), which is within the preferred ANSI chromaticity bin. The chromaticity of transmitted light through the filter remained within the ANSI bin even when the angle of incidence of light transmitted through the filter varied between 0 degrees and 30 degrees. FIG. 6B illustrates the transmittance of light through the optical filter as a function of wavelength of the light emitted. For Example 2, the transmittance of light through the filter was observed to be 96.67%.

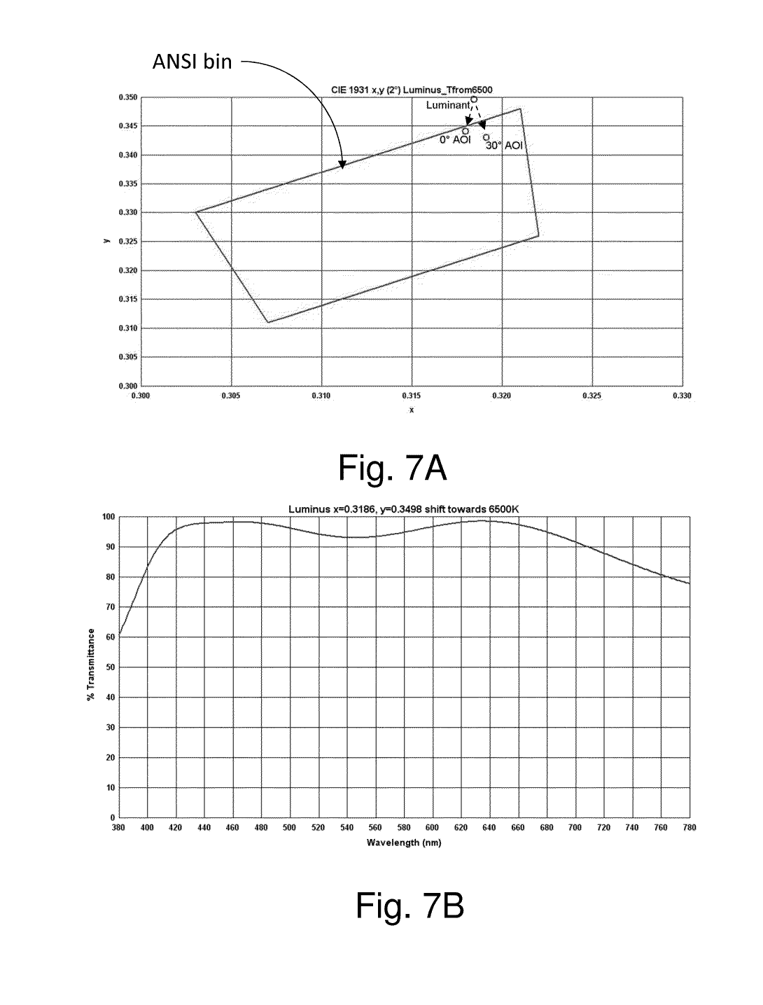

The shift in chromaticity when light emitted from the LED of Example 3 passed through the optical filter at 0 degree and 30 degree angles of incidence is shown in FIG. 7A. The initial chromaticity for the light emitted from the LED, without the optical filter in place, was (0.3186, 0.3498). The shifted chromaticity for the emitted light having passed through the optical filter at a 0 degree angle of incidence was (0.3180, 0.3441), which is within the preferred ANSI chromaticity bin. The chromaticity of transmitted light through the filter remained within the ANSI bin even when the angle of incidence of light transmitted through the filter varied between 0 degrees and 30 degrees. FIG. 7B illustrates the transmittance of light through the optical filter as a function of wavelength of the light emitted. For Example 3, the transmittance of light through the filter was observed to be 94.69%.

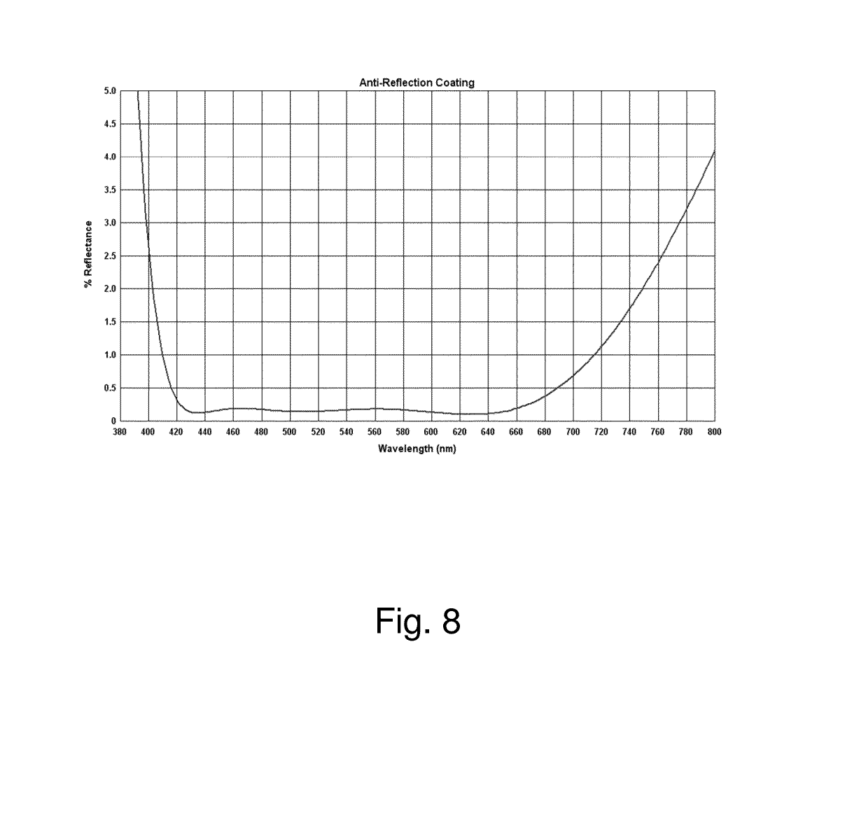

FIG. 8 depicts the percentage of light reflected as a function of the wavelength of light emitted from the LED chip. As shown, less than 0.5% reflectance was observed for light having a wavelength between 420 nm and 680 nm transmitted through each optical element.

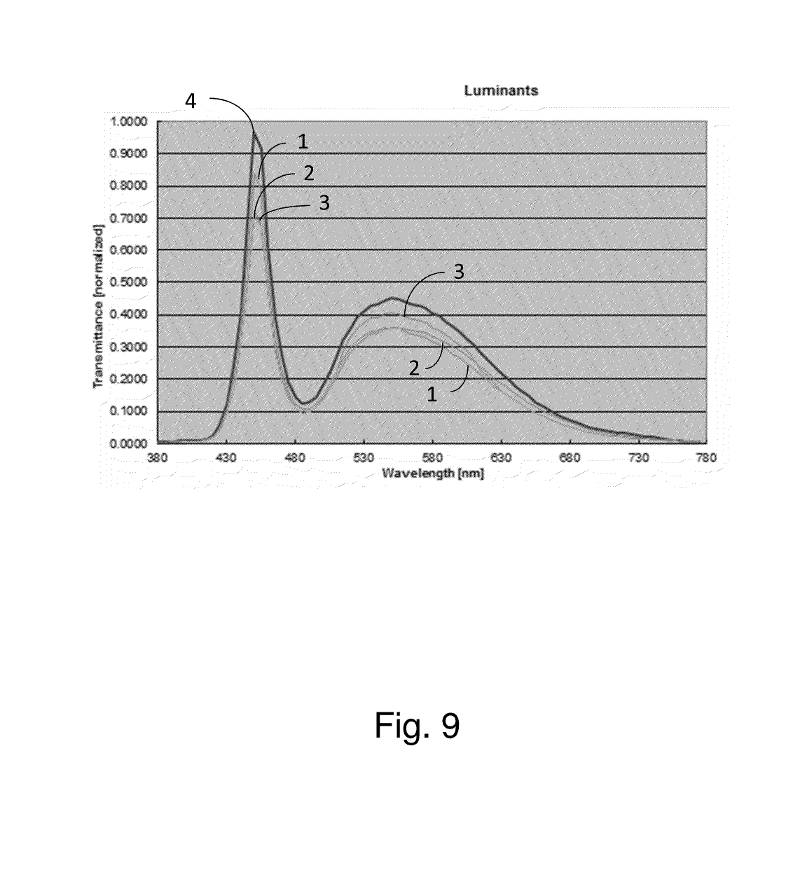

FIG. 9 depicts normalized transmittance spectra for each of Examples 1, 2, 3 as compared to a reference spectrum 4 where no loss of flux has occurred. As shown, the general shape of the spectrum for each of Examples 1, 2, 3 was not observed to be substantially different than the reference spectrum 4. Accordingly, the shift in chromaticity provided by the respective filters for each example did not result in a significant loss in flux.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

Having thus described several aspects of at least one embodiment of this invention, it is to be appreciated various alterations, modifications, and improvements will readily occur to those skilled in the art. Such alterations, modification, and improvements are intended to be part of this disclosure, and are intended to be within the spirit and scope of the invention. Accordingly, the foregoing description and drawings are by way of example only.

What is claimed is:

1. A light-emitting device comprising:
a chip including a multi-layer stack comprising semiconductor materials and including a light-generating region; and
a package associated with the chip, the package including an optical element configured to shift a chromaticity of light emitted from a surface of the light-generating region.

2. The light-emitting device of claim 1, wherein the optical element is configured to shift the chromaticity of the emitted light by a chromaticity magnitude of greater than about 0.002.

3. The light-emitting device of claim 2, wherein the optical element is configured to shift the chromaticity of the emitted light by a chromaticity magnitude of between about 0.002 and about 0.015.

4. The light-emitting device of claim 3, wherein the optical element is configured to shift the chromaticity of the emitted light by a chromaticity magnitude of between about 0.005 and about 0.01.

5. The light-emitting device of claim 3, wherein the optical element is configured to shift the chromaticity of the emitted light by a chromaticity magnitude of between about 0.002 and about 0.005.

6. The light-emitting device of claim 2, wherein the optical element is configured to shift the chromaticity of the emitted light by a chromaticity magnitude of between about 0.1 and about 0.2.

7. The light-emitting device of claim 1, wherein the optical element is configured to shift the chromaticity of the emitted light having a wavelength of between 100 nm and 1000 nm.

8. The light-emitting device of claim 7, wherein the optical element is configured to shift the chromaticity of the emitted light having a wavelength of between 435 nm and 665 nm.

9. The light-emitting device of claim 1, wherein the optical element is configured to reduce a flux of the emitted light.

10. The light-emitting device of claim 9, wherein the optical element is configured to reduce the flux of the emitted light by an amount less than about 10%.

11. The light-emitting device of claim 1, wherein the optical element comprises a filter configured to receive light emitted from the surface of the light-generating region.

12. The light-emitting device of claim 11, wherein the filter comprises a window having a coating disposed on a side of the window facing away from the surface of the light-generating region.

13. The light-emitting device of claim 12, wherein the coating includes a metal oxide comprising at least one of TiO₂, Nb₂O₃, ZnO, ZrO₂, Ta₂O₅ and SnO₂.

14. The light-emitting device of claim 11, wherein the filter comprises a window having an anti-reflective coating facing toward the surface of the light-generating region.

15. A method of operating a light-emitting device comprising:
emitting light from a surface of a chip, wherein the chip comprises a multi-layer stack of semiconductor materials and including a light-generating region; and
shifting a chromaticity of the emitted light with an optical element, wherein the optical element is part of a package associated with the chip.

16. The method of claim 15, wherein the shift in chromaticity of light emitted from the surface of the light-generating region comprises a shift in chromaticity magnitude of greater than about 0.002.

17. The method of claim 16, wherein the shift in chromaticity of light emitted from the surface of the light-generating region comprises a shift in chromaticity magnitude of between about 0.002 and about 0.015.

18. The method of claim 17, wherein the shift in chromaticity of light emitted from the surface of the light-generating region comprises a shift in chromaticity magnitude of between about 0.005 and about 0.01.

19. The method of claim 17, wherein the shift in chromaticity of light emitted from the surface of the light-generating region comprises a shift in chromaticity magnitude of between about 0.002 and about 0.005.

20. The method of claim 16, wherein the shift in chromaticity of light emitted from the surface of the light-generating region comprises a shift in chromaticity magnitude of between about 0.1 and about 0.2.

21. The method of claim 15, wherein emitting light from the surface of a chip comprises emitting light having a wavelength of between 100 nm and 1000 nm.

22. The method of claim 12, wherein emitting light from the surface of a chip comprises emitting light having a wavelength of between 435 nm and 665 nm.

23. The method of claim 15, wherein shifting the chromaticity of light emitted from the surface of the light-generating region comprises reducing a flux of the emitted light.

24. The method of claim 23, wherein the reduction in flux of the emitted light is less than about 10%.

25. The method of claim 15, wherein shifting the chromaticity of the emitted light comprises producing light falling within an ANSI chromaticity bin distribution.

26. The method of claim 25, wherein the chromaticity bin distribution is defined by points (0.303, 0.330), (0.321, 0.348), (0.322, 0.326) and (0.307, 0.311) on a x, y chromaticity map.
